(19) United States
(12) Patent Application Publication
(10) Pub. No.: US 2011/0308929 A1
(43) Pub. Date: Dec. 22, 2011

(54) TOUCH PANEL AND METHOD OF MANUFACTURING THE SAME

(75) Inventors: Jae Il Kim, Gyunggi-do (KR); Woon Chun Kim, Gyunggi-do (KR); Yong Soo Oh, Gyunggi-do (KR); Jong Young Lee, Gyunggi-do (KR)

(73) Assignee: SAMSUNG ELECTRO-MECHANICS CO., LTD., Gyunggi-do (KR)

(21) Appl. No.: 12/884,868

(22) Filed: Sep. 17, 2010

(30) Foreign Application Priority Data
Jun. 21, 2010 (KR) 1020100058480

(51) Int. Cl. H03K 17/975; C23C 14/34; B05D 5/12

(52) U.S. Cl. 200/600; 204/192.17; 427/108; 977/742

(57) ABSTRACT

Disclosed herein is a touch panel 100, including: a transparent electrode 120 including a conductive polymer and formed on one surface of a transparent substrate 110, connection electrodes 130 formed on both ends of the transparent electrode 120, and silver electrode 140 formed on the connection electrodes 130 to correspond to the connection electrodes 130, wherein the connection electrodes 130 prevent the transparent electrode 120 from contacting the silver electrodes 140. The connection electrode 130 is interposed between the transparent electrode 120 and the silver electrode 140 to prevent a chemical reaction between the transparent electrode 120 and the silver electrode 140, thereby maintaining electric resistance constantly.

### CROSS REFERENCE TO RELATED APPLICATION

This application claims the benefit of Korean Patent Application No. 10-2010-0058480, filed on Jun. 21, 2010, entitled “Touch. Panel And a Manufacturing Method The Same”, which is hereby incorporated by reference in its entirety into this application.

### BACKGROUND OF THE INVENTION

1. Technical Field

The present invention relates to a touch panel and a method of manufacturing the same.

2. Description of the Related Art

Alongside the growth of computers using digital technology, devices assisting the computers have also been developed, and personal computers, portable transmitters and other personal information processors execute processing of text and graphics using a variety of input devices such as a keyboard and a mouse.

While the rapid advancement of the information-based society has been widening the use of computers more and more, there have been occurring the problems of it being difficult to efficiently operate products using only the keyboard and mouse as being currently responsible for the input device function. Thus, the demand for a device that is simple, does not malfunction, and has the capability to easily input information is increasing.

Furthermore, current techniques for input devices exceed the level of fulfilling general functions and thus are progressing towards techniques related to high reliability, durability, innovation, designing and manufacturing. To this end, a touch panel has been developed as an input device capable of inputting information such as text and graphics.

The touch panel is mounted on the display surface of an image display device such as an electronic organizer, a flat panel display including a liquid crystal display (LCD), a plasma display panel (PDP), an electroluminescence (El) element or the like, or a cathode ray tube (CRT), so that a user selects the information desired while viewing the image display device.

The touch panel is classifiable as a resistive type, a capacitive type, an electromagnetic type, a surface acoustic wave (SAW) type, and an infrared type. The type of touch panel selected is one that is adapted for an electronic product in consideration of not only signal amplification problems, resolution differences and the degree of difficulty of designing and manufacturing technology but also in light of optical properties, electrical properties, mechanical properties, resistance to the environment, input properties, durability and economic benefits of the touch panel. In particular, resistive and capacitive types are prevalently used in a broad range of fields currently.

FIG. 1 is a cross-sectional view of a touch panel according to the prior art. Problems of the prior art will be described with reference to the figure.

As shown in FIG. 1, a touch panel 10 according to the prior art is configured to include a transparent electrode 13 formed on a transparent substrate 11 to sense the touch of an input unit, and a silver electrode 15 formed on both ends of the transparent electrode 13 to transfer an electrical signal between the transparent electrode 13 and a controller. Herein, the transparent electrode 13 is generally made of indium tin oxide (ITO), whereas the silver electrode 15 is made of silver (Ag). Therefore, a chemical reaction generates between the transparent electrode 13 and the silver electrode 15 to increase electric resistance, such that current does not smoothly flow. In addition, since the transparent electrode 13 and the silver electrode 15 have weak adhesion therebetween, the silver electrode 15 is easily separated from the transparent electrode 13, thereby degrading durability of the touch panel 10.

### SUMMARY OF THE INVENTION

The present invention has been made in an effort to provide a touch panel capable of preventing a chemical reaction between a transparent electrode and a silver electrode and preventing the silver electrode from being separated from the transparent electrode by adopting a connection electrode, and a method of manufacturing the same.

A touch panel according to a preferred embodiment of the present invention includes: a transparent electrode including a conductive polymer and formed on one surface of a transparent substrate; connection electrodes formed on both ends of the transparent electrode; and silver electrodes formed on the connection electrodes to correspond to the connection electrodes, wherein the connection electrodes prevent the transparent electrode from contacting the silver electrodes.

Herein, the conductive polymer includes poly-3, 4-ethylenedioxythiophene/polystyrenesulfonate (PEDOT/PSS), polyacetylene, or polyphenylenevinylene.

Further, the connection electrode is made of gold (Au), nickel (Ni), platinum (Pt), carbons, polyaniline or a mixture thereof.

Further, the carbons include a carbon black, a carbon nano tube, or a carbon nano fiber.

A method of manufacturing a touch panel according to a preferred embodiment of the present invention includes: (A) forming a transparent electrode including a conductive polymer on one surface of a transparent substrate; (B) forming connection electrodes on both ends of the transparent electrode; and (C) forming silver electrodes on the connection electrodes to correspond to the connection electrodes, wherein the connection electrodes prevent the transparent electrode from contacting the silver electrodes.

Herein, at the forming the connection electrodes, the connection electrodes are formed by a sputtering process.

Herein, at the forming the transparent electrode, the conductive polymer includes poly-3, 4-ethylenedioxythiophene/polystyrenesulfonate (PEDOT/PSS), polyacetylene, or polyphenylenevinylene.

Herein, at the forming the connection electrodes, the connection electrode is made of gold (Au), nickel (Ni), platinum (Pt), carbons, polyaniline or a mixture thereof.

Herein, the carbons include a carbon black, a carbon nano tube, or a carbon nano fiber.

### BRIEF DESCRIPTION OF THE DRAWINGS

FIG. 1 is a cross-sectional view of a touch panel according to the prior art;

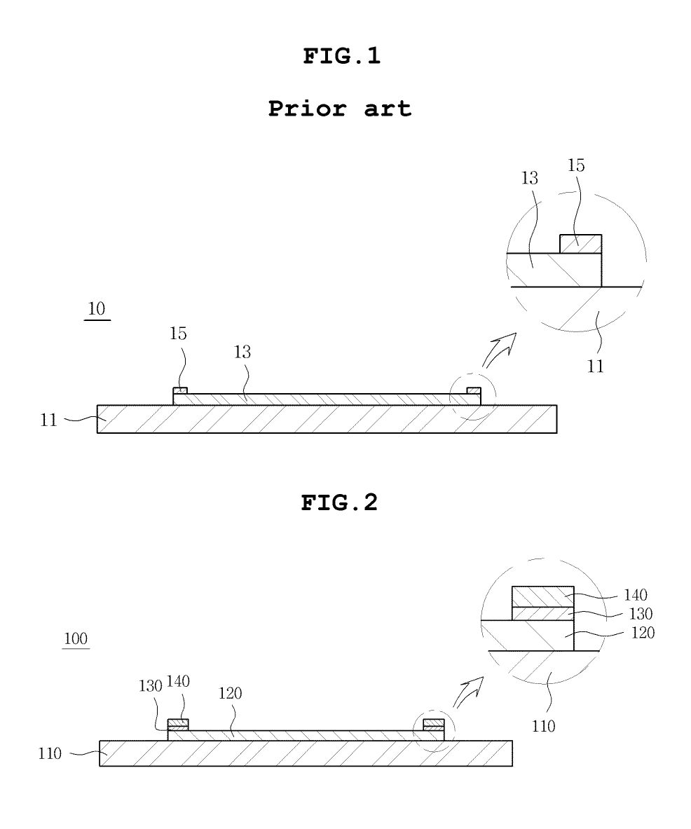

FIG. 2 is a cross-sectional view of a touch panel according to a preferred embodiment of the present invention;

FIGS. 3 to 5 are cross-sectional views of a touch panel according to another preferred embodiment of the present invention; and

FIGS. 6 and 8 are cross-sectional views showing a method of manufacturing a touch panel according to a preferred embodiment of the present invention in a processing sequence.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, in describing the present invention, a detailed description of related known functions or configurations will be omitted so as not to obscure the gist of the present invention.

Hereinafter, preferred embodiments of the present invention will be described in detail with reference to the accompanying drawings.

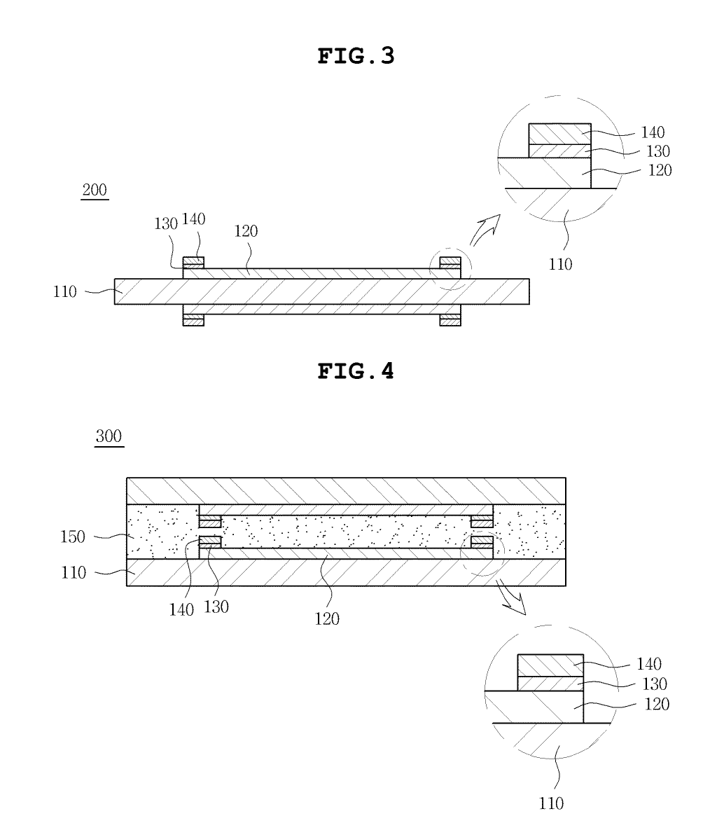

FIG. 2 is a cross-sectional view of a touch panel according to a preferred embodiment of the present invention.

As shown in FIG. 2, a touch panel 100 according to the present embodiment includes a transparent electrode 120 including a conductive polymer and formed on one surface of a transparent substrate 110, connection electrodes 130 formed on both ends of the transparent electrode 120, and silver electrode 140 formed on the connection electrodes 130 to correspond to the connection electrodes 130, wherein the connection electrodes 130 prevent the transparent electrode 120 from contacting the silver electrodes 140.

The transparent substrate 110 serves to support the transparent electrode 120, the connection electrode 130, and the silver electrode 140. The material of the transparent substrate 110 is not particularly limited, and may include polyethyleneterephthalate (PET), polycarbonate (PC), polymethylmethacrylate (PMMA), polyethylenenaphthalate (PEN), polyethersulfone (PES), cyclic olefin copolymer (COC), triacetylcellulose (TAC) film, polyvinyl alcohol (PVA) film, polyimide (PI) film, polystyrene (PS), biaxially oriented polystyrene (BOPS; containing K resin), glass or tempered glass and so on.

The transparent electrode 120 serves to generate signals when a user touches the panel and allow a controller to recognize touched coordinates. The transparent electrode 120 is formed on one surface of the transparent substrate 110. Herein, the transparent electrode 120 is formed using a conductive polymer having excellent flexibility and a simple coating process. At this time, the conductive polymer includes poly-3, 4-ethylenedioxythiophene/polystyrenesulfonate (PEDOT/PSS), polyacetylene, polyphenylenevinylene, or the like. Meanwhile, it is preferable that a high frequency process or a primer process is performed on one surface of the transparent substrate 110 in order to activate a surface thereof (improve adhesion) before forming the transparent electrode 120 on one surface of the transparent substrate 110.

The connection electrode 130 is formed on both ends of the transparent electrode 120 to prevent the transparent electrode 120 from directly contacting the silver electrode 140. Herein, the connection electrode 130 is adopted to prevent a chemical reaction between the transparent electrode 120 and the silver electrode 140 from being generated and prevent the silver electrode 140 from being separated. It is preferable that the connection electrode 130 is selected from a material having less difference in physical property with the silver electrode 140. Therefore, it is preferable that the connection electrode 130 is made of gold (Au), nickel (Ni), platinum (Pt), carbons, polyaniline or a mixture thereof. Herein, the carbons include a carbon black, a carbon nano tube, or a carbon nano fiber. Meanwhile, the connection electrodes 130 are formed on the transparent electrode 120 by a sputtering process, thereby making it possible to make the thickness thereof uniform and increase adhesion between the transparent electrode 120 and the connection electrodes 130.

The touch panel 100 according to the present invention adopts the connection electrode 130, thereby making it possible to prevent the chemical reaction between the transparent electrode 120 and the silver electrode 140 from being generated and thus maintain electric resistance constantly. In addition, as the connection electrode 130 is made of a material having less difference in physical property with the silver electrode 140 to be described below, it is possible to relatively improve adhesion as compared to the prior art, thereby making it possible to prevent the silver electrode 140 from being separated.

The silver electrode 140 is formed on the connection electrode 130 to receive an electrical signal from the transparent electrode 120. Herein, in order to prevent the chemical reaction with the transparent electrode 120 from being generated, the silver electrodes 140 should be selectively formed only on the upper parts of the connection electrodes 130 so as to correspond to the connection electrodes 130. At this time, the silver electrode 140 may be printed using a silk screen printing method, a gravure printing method, an inkjet printing method, or the like. In addition, it is preferable that the silver electrode 140 is made of silver (Ag) paste or organic Ag having superior electrical conductivity. Meanwhile, even though the silver electrodes 140 are shown to be connected to both ends of the transparent electrode 120, this is only exemplary but the silver electrodes 140 may also be connected to only one end of the transparent electrode 120 according to the type of touch panel and in this case, the connection electrodes 130 are also formed on only one end of the transparent electrode 120.

The silver electrode 140 is conducted with a flexible printed circuit (FPC) cable through wirings collected at one side of the transparent substrate 110 and thus, the silver electrode 140 is connected to a controller through the wirings and the FPC cable.

As described above, the touch panel 100 according to the present embodiment may be manufactured as not only a self capacitive touch panel or a mutual capacitive touch panel using the transparent electrode 120 with a single layer structure but also various types of touch panels including the configuration to be described below.

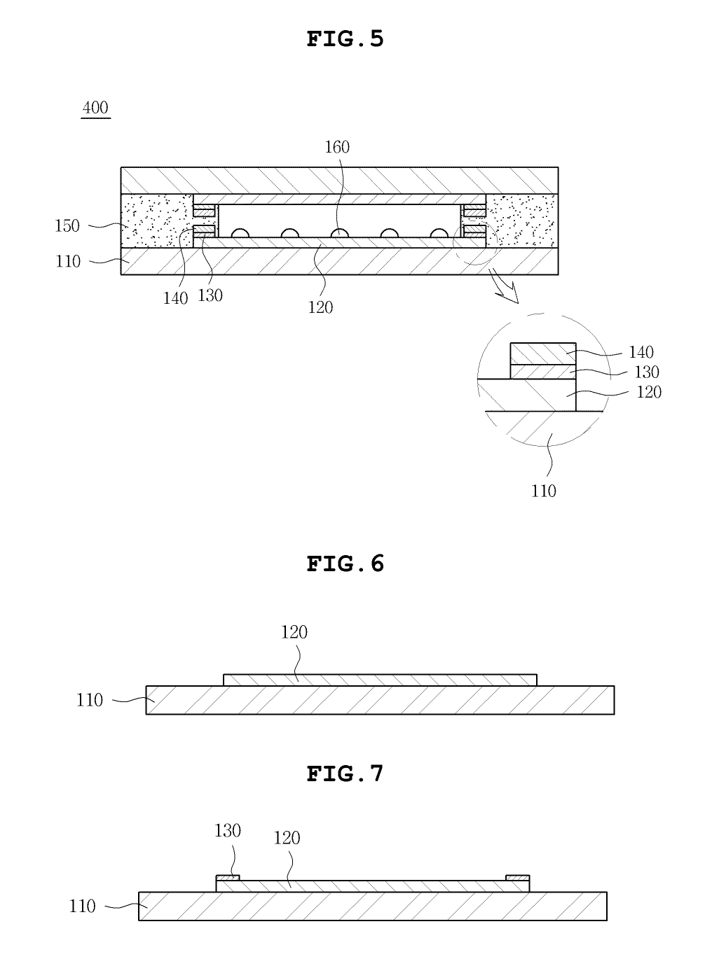

FIGS. 3 to 5 are cross-sectional views of a touch panel according to another preferred embodiment of the present invention.

As shown in FIGS. 3 to 5, a mutual capacitive touch panel 200 (see FIG. 3) may be manufactured by forming transparent electrodes 120 on both surfaces of a transparent substrate 110, respectively. Besides, a mutual capacitive touch panel 300 (see FIG. 4) or a resistive touch panel 400 (see FIG. 5) may be manufactured by preparing two transparent substrates 110 having the transparent electrode 120 formed on one surface thereof and bonding the two transparent substrates 110 by through the adhesive layer 150 so that the transparent electrodes 120 are opposite to each other. Herein, in the case of the mutual capacitive touch panel 300 (see FIG. 4), an adhesive layer 150 is bonded to the entire surface of the transparent electrode 120 so that the two transparent electrodes 120 opposite to each other are insulated. In the case of the resistive touch panel 400 (see FIG. 5), the adhesive layer 150 is bonded to only the edges of the touch electrodes 120 so that the two transparent electrodes 120 opposite to each other contact when a user's pressure is applied and dot spacers 160 providing repulsive force are formed on the transparent electrodes 120 so that the transparent electrodes 120 return to their original positions when the user's pressure is removed.

Meanwhile, in the present invention, the connection electrodes 130 are formed between the transparent electrodes 120 and the silver electrodes 140, thereby also making it possible to prevent a chemical reaction therebetween from being generated and prevent the silver electrodes 140 from being separated.

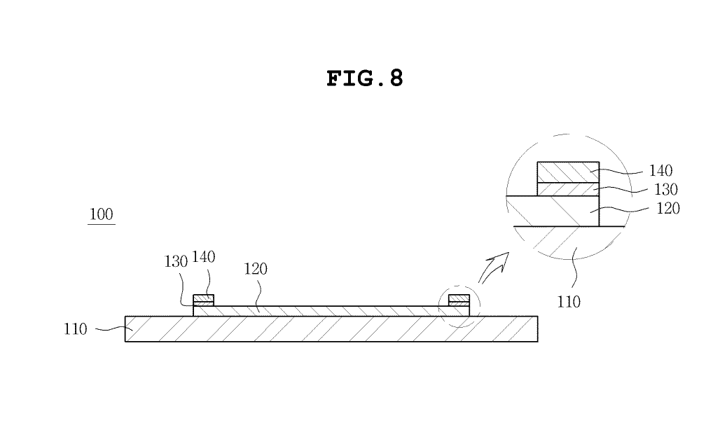

FIGS. 6 and 8 are cross-sectional views showing a method of manufacturing a touch panel according to a preferred embodiment of the present invention in a processing sequence.

As shown in FIGS. 6 to 8, a method of manufacturing a touch panel according to the present embodiment includes (A) forming a transparent electrode 120 including a conductive polymer on one surface of a transparent substrate 110, (B) forming connection electrodes 130 on both ends of the transparent electrode 120, and (C) forming silver electrodes 140 on the connection electrodes 130 to correspond to the connection electrodes 130, wherein the connection electrodes 130 prevent the transparent electrode 120 from contacting the silver electrodes 140.

First, as shown in FIG. 6, the transparent electrode 120 including the conductive polymer is formed on one surface of the transparent substrate 110. Herein, the transparent electrode 120 is made of the conductive polymer including poly-3, 4-ethylenedioxythiophene/polystyrenesulfonate (PEDOT/PSS), polyacetylene, polyphenylenevinylene, or the like. Meanwhile, the process for forming the transparent electrode 120 is not particularly limited, but the transparent electrode 120 may be formed using a dry patterning process such as a sputtering, evaporation, or the like, or a direct patterning process such as a screen printing method, a gravure printing method, an inkjet printing method, or the like.

Then, as shown in FIG. 7, the connection electrodes 130 are formed on both ends of the transparent electrode 120. Herein, it is preferable that the connection electrode 130 is made of gold (Au), nickel (Ni), platinum (Pt), carbons, polyaniline or a mixture thereof, wherein the carbons include a carbon black, a carbon nano tube, or a carbon nano fiber. Meanwhile, the connection electrodes 130 may be formed on the transparent electrode 120 by a sputtering process. A sputtering process is a sort of process of forming a physical thin film and is a method of depositing the connection electrode 130 on the transparent electrode 120 by forming steam particles through a physical method. In other words, as ion particles having large kinetic energy collide with a target material that is the composition of the connection electrode 130, the target material is discharged and then the discharged target material is attached to the transparent electrode 120, thereby completing the connection electrode 130. The connection electrodes 130 are formed by a sputtering process, thereby making it possible to make the thickness of the connection electrodes 130 uniform and increase adhesion between the transparent electrode 120 and the connection electrodes 130.

Then, as shown in FIG. 8, the silver electrodes 140 are formed on the connection electrodes 130 to correspond to the connection electrodes 130. Herein, the silver electrode 140 may be printed using a silk screen printing method, a gravure printing method, an ink-jet printing method or the like. In addition, since the silver electrodes 140 are formed on the upper parts of the connection electrodes 130 to correspond to the connection electrodes 130, they do not directly contact the transparent electrode 120, thereby making it possible to prevent a chemical reaction between the transparent electrode 120 and the silver electrodes 140 from being generated and thus to maintain electric resistance constantly. In addition, the silver electrode 140 is formed on the connection electrode 130 made of a material having less difference in physical property with the silver electrode 140 to improve adhesion therebetween, thereby making it possible to prevent the silver electrode 140 from being separated from the connection electrode 130.

According to the present invention, the connection electrode is interposed between the transparent electrode and the silver electrode to prevent a chemical reaction between the transparent electrode and the silver electrode, thereby making it possible to maintain electric resistance constantly.

In addition, according to the present invention, the silver electrode is formed on the connection electrode having less difference in physical property with the silver electrode to relatively improve adhesion as compared to the prior art, thereby making it possible to prevent the silver electrode from being separated.

Although the preferred embodiments of the present invention have been disclosed for illustrative purposes, they are for specifically explaining the present invention and thus a touch panel and a method of manufacturing the same according to the present invention are not limited thereto, but those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A touch panel, comprising:
a transparent electrode including a conductive polymer and formed on one surface of a transparent substrate;
connection electrodes formed on both ends of the transparent electrode; and
silver electrodes formed on the connection electrodes to correspond to the connection electrodes,
wherein the connection electrodes prevent the transparent electrode from contacting the silver electrodes.

2. The touch panel as set forth in claim 1, wherein the conductive polymer includes poly-3, 4-ethylenedioxythiophene/polystyrenesulfonate (PEDOT/PSS), polyacetylene, or polyphenylenevinylene.

3. The touch panel as set forth in claim 1, wherein the connection electrode is made of gold (Au), nickel (Ni), platinum (Pt), carbons, polyaniline or a mixture thereof.

4. The touch panel as set forth in claim 3, wherein the carbons include a carbon black, a carbon nano tube, or a carbon nano fiber.

5. A method of manufacturing a touch panel, comprising:
(A) forming a transparent electrode including a conductive polymer on one surface of a transparent substrate;
(B) forming connection electrodes on both ends of the transparent electrode; and
(C) forming silver electrodes on the connection electrodes to correspond to the connection electrodes,
wherein the connection electrodes prevent the transparent electrode from contacting the silver electrodes.

6. The method of manufacturing a touch panel as set forth in claim 5, wherein at the forming the connection electrodes, the connection electrodes are formed by a sputtering process.

7. The method of manufacturing a touch panel as set forth in claim 5, wherein at the forming the transparent electrode, the conductive polymer includes poly-3, 4-ethylenedioxythiophene/polystyrenesulfonate (PEDOT/PSS), polyacetylene, or polyphenylenevinylene.

8. The method of manufacturing a touch panel as set forth in claim 5, wherein at the forming the connection electrodes, the connection electrode is made of gold (Au), nickel (Ni), platinum (Pt), carbons, polyaniline or a mixture thereof.

9. The method of manufacturing a touch panel as set forth in claim 8, wherein the carbons include a carbon black, a carbon nano tube, or a carbon nano fiber.
